(19) United States
(12) Patent Application Publication
(10) Pub. No.: US 2005/0022857 A1
(43) Pub. Date: Feb. 3, 2005

(54) Solar cell interconnect structure

(76) Inventors: Shandor G. Daroczi, Santa Clara, CA (US); Matthew B. Piper, San Jose, CA (US); Neil Kaminar, Boulder Creek, CA (US)

Correspondence Address: OKAMOTO & BENEDICTO, LLP, P.O. BOX 641330, SAN JOSE, CA, 95164, US

(21) Appl. No.: 10/633,188

(22) Filed: Aug. 1, 2003

(51) Int. Cl. H01L 31/00

(52) U.S. Cl. 136/244; 136/256

(57) ABSTRACT

In one embodiment, backside-contact solar cells in a solar cell array are connected using separate pieces of interconnect leads. Each interconnect lead may electrically connect a contact point on a backside-contact solar cell to a corresponding contact on another backside-contact solar cell. Each interconnect lead may be curved to provide strain relief.

### BACKGROUND OF THE INVENTION

1. Field Of The Invention

The present invention relates generally to solar cells, and more particularly but not exclusively to structures for interconnecting solar cells.

2. Description Of The Background Art

Solar cells, also referred to as “photovoltaic cells,” are well known devices for converting solar radiation to electrical energy. They may be fabricated on a semiconductor wafer using semiconductor processing technology. Generally speaking, a solar cell may be fabricated by forming p-doped and n-doped regions in a silicon substrate. Solar radiation impinging on the solar cell creates electrons and holes that migrate to the p-doped and n-doped regions, thereby creating voltage differentials between the doped regions. In a backside-contact solar cell, the doped regions are coupled to conductive leads on the backside of the solar cell to allow an external electrical circuit to be coupled to and be powered by the solar cell. Backside-contact solar cells are disclosed in U.S. Pat. Nos. 5,053,083 and 4,927,770, which are both incorporated herein by reference in their entirety.

Several solar cells may be connected together to form a solar cell array. In a solar cell array, a conductive area coupled to a p-doped region (hereinafter “positive area”) of one solar cell is connected to a conductive area coupled to an n-doped region (hereinafter “negative area”) of an adjacent solar cell. The positive area of the adjacent solar cell is then connected to a negative area of a next adjacent solar cell and so on. This chaining of solar cells may be repeated to connect several solar cells in series to increase the output voltage of the solar cell array. Backside-contact solar cells have been connected together using a relatively long, single strip of perforated conductive material. U.S. Pat. No. 6,313,395, which is incorporated herein by reference in its entirety, also discloses the interconnection of several backside-contact solar cells to form a solar cell array.

### SUMMARY

In one embodiment, backside-contact solar cells in a solar cell array are connected using separate pieces of interconnect leads. Each interconnect lead may electrically connect a contact point on a backside-contact solar cell to a corresponding contact point on another backside-contact solar cell. Each interconnect lead may be curved to provide strain relief.

These and other features of the present invention will be readily apparent to persons of ordinary skill in the art upon reading the entirety of this disclosure, which includes the accompanying drawings and claims.

### DESCRIPTION OF THE DRAWINGS

FIG. 1A shows an exploded view of a solar cell module in accordance with an embodiment of the present invention.

FIG. 1B shows a plan view of the solar cell module of FIG. 1A.

FIG. 2 schematically illustrates the interconnection of several solar cells to form a solar cell array in accordance with an embodiment of the present invention.

FIGS. 3A, 3B, and 3C show various views of a backside-contact solar cell in accordance with an embodiment of the present invention.

FIGS. 4A, 4B, and 4C show various views of an interconnect lead in accordance with an embodiment of the present invention.

FIGS. 5A and 5B show various views of an interconnect lead in accordance with an embodiment of the present invention.

FIG. 6A shows a perspective view illustrating the interconnection of two solar cells in accordance with an embodiment of the present invention.

FIG. 6B shows a magnified view of a portion of FIG. 6A.

The use of the same reference label in different drawings indicates the same or like components. Drawings are not necessarily to scale unless otherwise noted.

### DETAILED DESCRIPTION

In the present disclosure, numerous specific details are provided such as examples of components, materials, dimensions, and methods to provide a thorough understanding of embodiments of the invention. Persons of ordinary skill in the art will recognize, however, that the invention can be practiced without one or more of the specific details. In other instances, well-known details are not shown or described to avoid obscuring aspects of the invention.

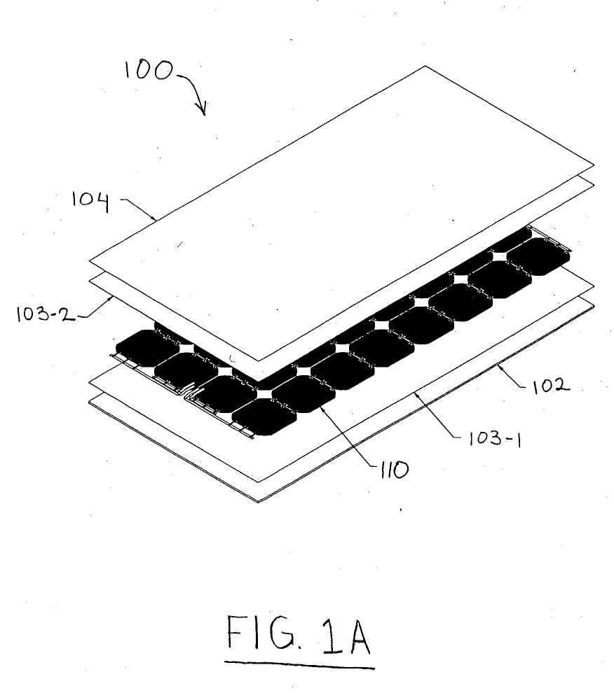

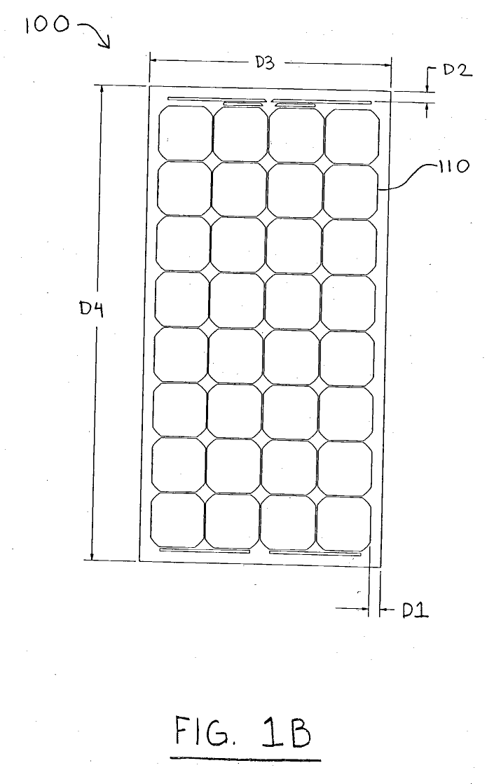

FIG. 1A shows an exploded view of a solar cell module 100 in accordance with an embodiment of the present invention. Module 100 may comprise a solar cell array 110 that is laminated between layers 102,103 (i.e., 103-1, 103-2), and 104. Layers 103 may comprise sheets of an EVA (ethylene vinyl acetate) material, layer 102 may comprise glass, and layer 104 may comprise a sheet of plastic (also referred to as a “back sheet”). Solar cell array 110 and layers 102, 103, and 104 may be placed in a laminator where they are conventionally bound together to form module 100. In a typical application, module 100 is oriented such that glass layer 102 faces the sun. Accordingly, the front or sun sides of the solar cells of solar cell array 110 are towards glass layer 102, while the backsides of the solar cells are towards layer 104.

FIG. 1B shows a plan view of solar cell module 100 as seen from layer 102. The solar cells of solar cell array 110 are backside contact solar cells. Interconnect leads (also known as “tabs”) electrically coupling the solar cells together are attached to the backsides of the solar cells. In one embodiment, module 100 has a dimension D1 of about, 0.68 inch, a dimension D2 of about 0.66 inch, a dimension D3 of about 14.75 inches, and a dimension D4 of about 29 inches. The aforementioned dimensions, and other dimensions disclosed herein, are provided for illustration purposes only. These dimensions may be varied to meet the needs of specific applications.

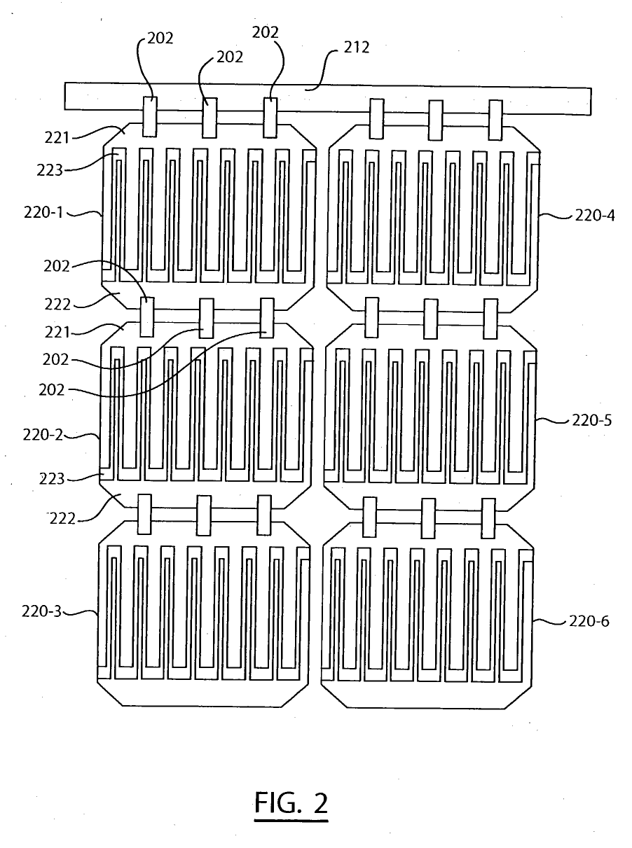

FIG. 2 schematically illustrates the interconnection of several solar cells 220 (i.e., 220-1, 220-2, . . . ) to form a solar cell array 110 in accordance with an embodiment of the present invention. FIG. 2 does not show all solar cells and bus bars of solar cell array 110 to avoid cluttering the figure. Solar cells 220 are shown with their backsides facing up. Solar cells 220 are backside contact solar cells in that electrical connections to their doped regions are made from their backsides.

Using solar cell 220-1 as an example, a solar cell 220 may include an electrically conductive area 221 forming interdigitated metal contacts with an electrically conductive area 222. Conductive areas 221 and 222 may comprise stacks of electrically conductive materials with tin on the top surfaces, for example. An insulator area 223 separates conductive area 221 from conductive area 222. Conductive areas 221 and 222 are of differing electrical polarity. In one embodiment, conductive area 221 is electrically coupled to a p-doped region and is thus of positive polarity, while conductive area 222 is electrically coupled to an n-doped region and is thus of negative polarity. Solar radiation impinging on the front side of a solar cell 220 results in an electrical potential difference between conductive areas 221 and 22. The conductive area 221 of one solar cell 220 may be connected to the conductive area 222 of another solar cell 220, and so on, to serially connect the solar cells and form a solar cell array 110. Note that conductive areas 221 and 222 are only schematically illustrated in FIG. 2; their actual dimensions and patterns will vary depending on the particulars of the solar cell.

Solar cells 220 may be fabricated using the teachings of the following commonly-assigned disclosures, which are incorporated herein by reference in their entirety: U.S. application Ser. No. 10/412,638, entitled “Improved Solar Cell and Method of Manufacture,” filed on Apr. 10, 2003 by William P. Mulligan, Michael J. Cudzinovic, Thomas Pass, David Smith, Neil Kaminar, Keith McIntosh, and Richard M. Swanson; and U.S. application Ser. No. 10/412,711, entitled “Metal Contact Structure For Solar Cell And Method Of Manufacture,” filed on Apr. 10, 2003 by William P. Mulligan, Michael J. Cudzinovic, Thomas Pass, David Smith, and Richard M. Swanson. The present invention is not limited to the backside-contact solar cells described in the just mentioned disclosures; embodiments of the present invention may be employed to interconnect backside-contact solar cells in general.

In one embodiment, solar cells 220 are connected together using interconnect leads 202. Each end of an interconnect lead 202 may be connected to a contact point on a conductive area of a solar cell 220. The contact point may be a pad or simply a designated region on the conductive area. Each end of an interconnect lead 202 may be soldered onto a contact point, for example.

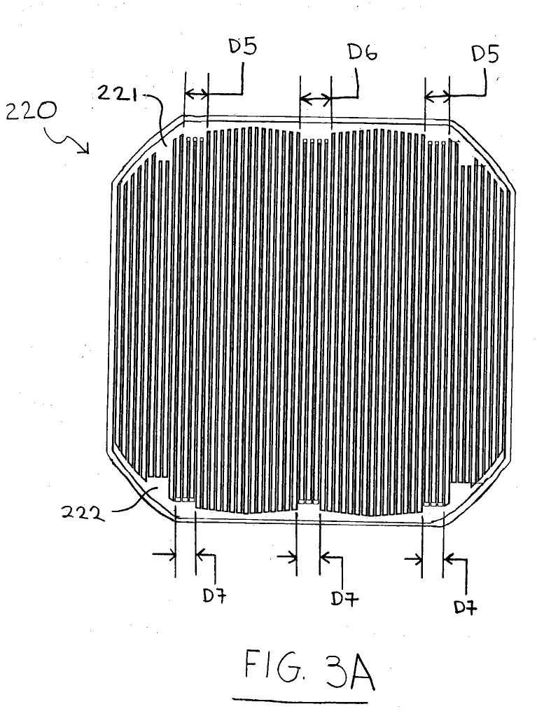

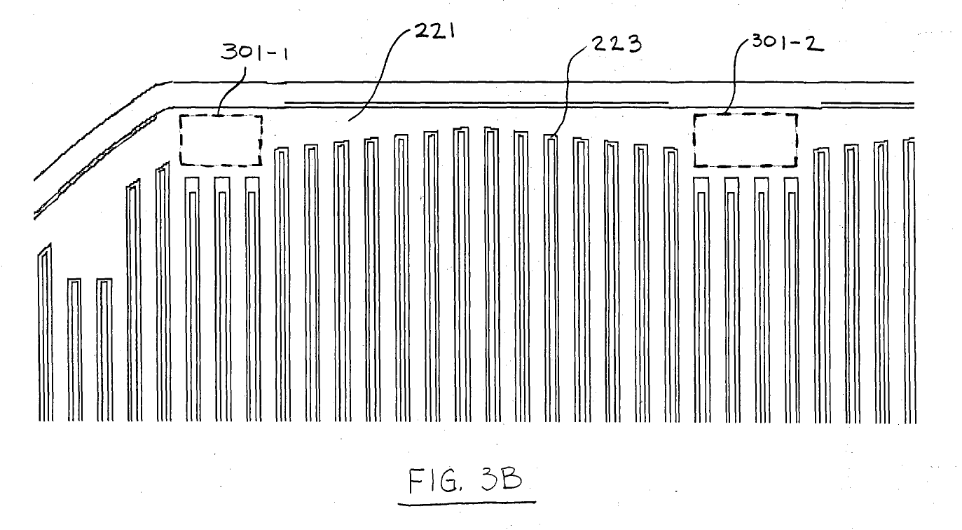

As shown in FIG. 2, several separate interconnect leads 202 are employed to connect one solar cell 220 to another. Among other advantages over a single, relatively long interconnect lead, several separate interconnect leads 202 require less interconnect material, provide more room for interdigitated contacts (see FIG. 3A), and lower the weight of the solar cell array.

In one embodiment, three interconnect leads 202 are employed between two adjacent solar cells to provide redundancy in the event of a failure of one interconnect lead. An electrically conductive bus bar 212 may also be employed to connect one solar cell 220 to another. In the example of FIG. 2, a bus bar 212 is employed to electrically couple solar cell 220-1 to solar cell 220-4.

FIG. 3A shows a plan view of a solar cell 220 in accordance with an embodiment of the present invention. FIG. 3A shows solar cell 220 with its backside facing up. Because several interconnect leads 202 require relatively small contact point space on a conductive area, the conductive area has more room for interdigitated metal contacts. In the example of FIG. 3A, the contact points are on conductive areas generally bounded by dimensions D5, D6, and D7. In one embodiment, dimensions D5 are about 7.48 mm, dimension D6 is about 9.6 mm, and dimensions D7 are about 6.77 mm. Solar cell 220 may be 0.25 mm thick, and occupy a 125 mm by 125 mm square area with radiused corners that are 150 mm in diameter. The above dimensions are exemplary and may vary depending on the application.

FIG. 3B shows a magnified view of an upper portion of the solar cell 220 of FIG. 3A. In FIG. 3B, two contact points on conductive area 221 are generally bounded by dashed boxes 301-1 and 301-2. A third contact point on conductive area 221 is not visible in FIG. 3B. Similarly, FIG. 3C shows a magnified view of a lower portion of the solar cell 220 of FIG. 3A. In FIG. 3C, two contact points on conductive area 222 are generally bounded by dashed boxes 302-1 and 302-2. A third contact point on conductive area 222 is not visible in FIG. 3C.

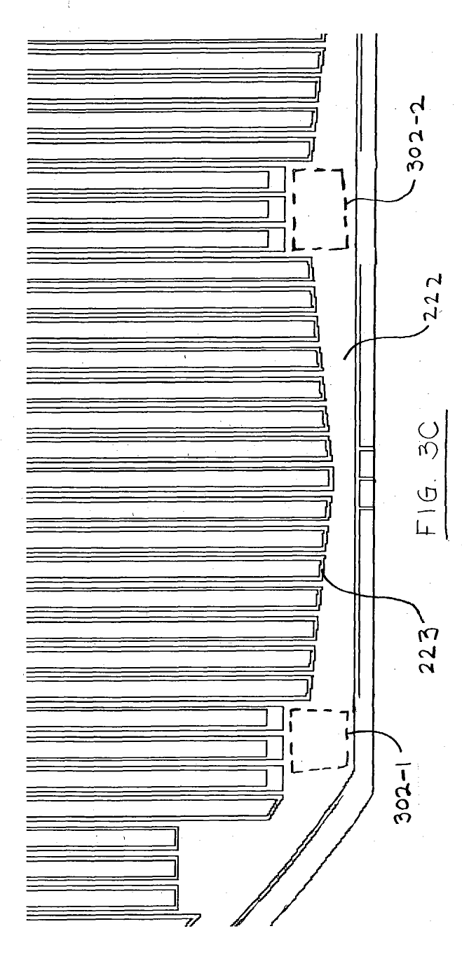

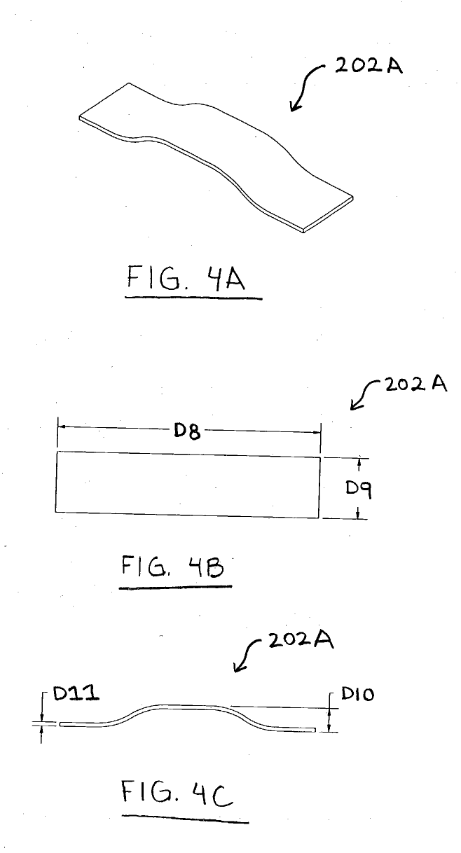

Referring now to FIG. 4A, there is shown a perspective view of an interconnect lead 202A in accordance with an embodiment of the present invention. Interconnect lead 202A is a specific embodiment of interconnect leads 202 shown in FIG. 2. In one embodiment, interconnect lead 202A is curved to advantageously allow for expansion and contraction when the solar cell array is exposed to hot (e.g., daytime) or cold (e.g., nighttime) environments. That is, the curve serves as a strain relief. In one embodiment, interconnect lead 202A comprises copper that is coated with tin. The tin protects the copper from corrosion and facilitates soldering of interconnect lead 202A onto a contact point. The copper may also be coated with other materials, such as solder. The copper is preferably soft, such as annealed electrolytic tough pitch (ETP) copper, to provide added strain relief. FIG. 4B is a plan view showing interconnect lead 202A as a flat piece of conductive material prior to being curved, while FIG. 4C is a side view showing interconnect lead 202A after being curved. In one embodiment, referring to FIGS. 4B and 4C, dimension D8 is about 0.344 inch, dimension D9 is about 0.079 inch, dimension D10 is about 0.031 inch, and dimension D11 is about 0.005 inch.

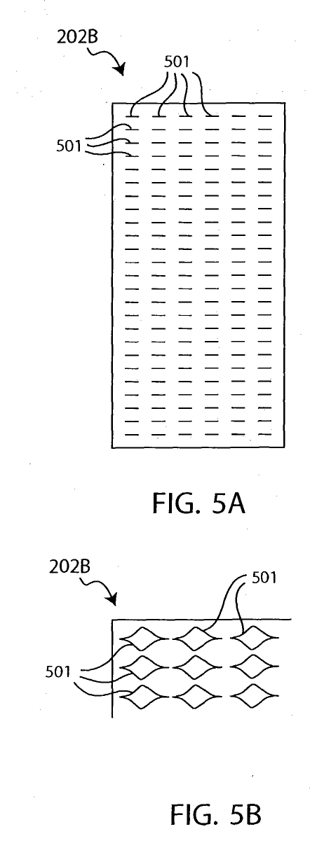

FIG. 5A shows an interconnect lead 202B in accordance with an embodiment of the present invention. Interconnect lead 202B is a specific embodiment of interconnect lead 202 shown in FIG. 2. In one embodiment, interconnect lead 202B is a strip of electrically conductive material such as copper. Interconnect lead 202B may be perforated for strain relief. For example, slits 501 may be formed on interconnect lead 202B by stamping. Thereafter, interconnect lead 202B may be stretched (i.e., expanded) to open up slits 501 as shown in FIG. 5B. Stretching interconnect lead 202B makes it more pliable for added strain relief. Expanded, meshed-like materials for fabricating interconnect leads are also available from Exmet Corporation of Naugatuck, Conn.

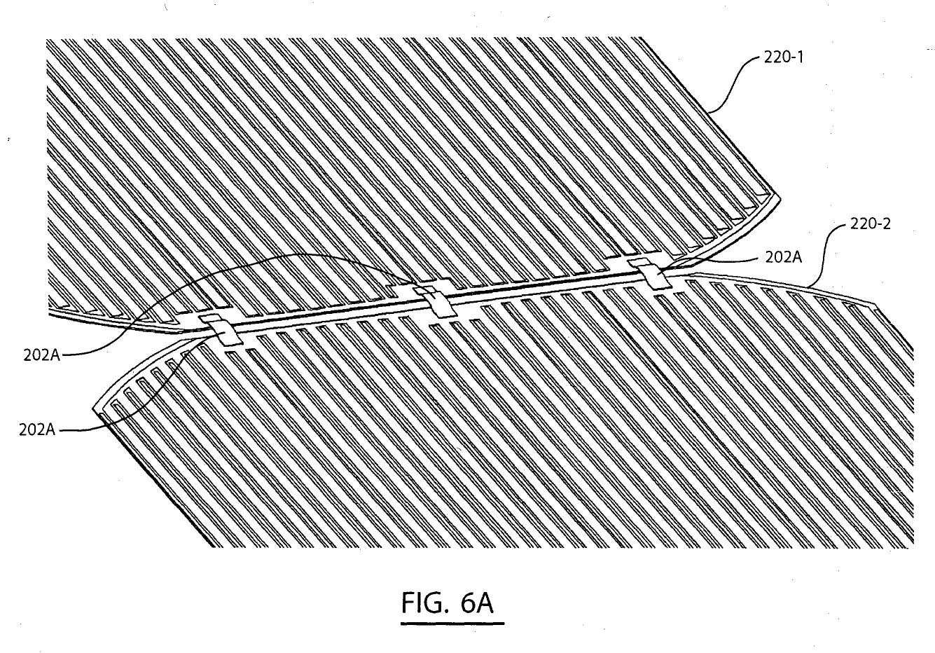

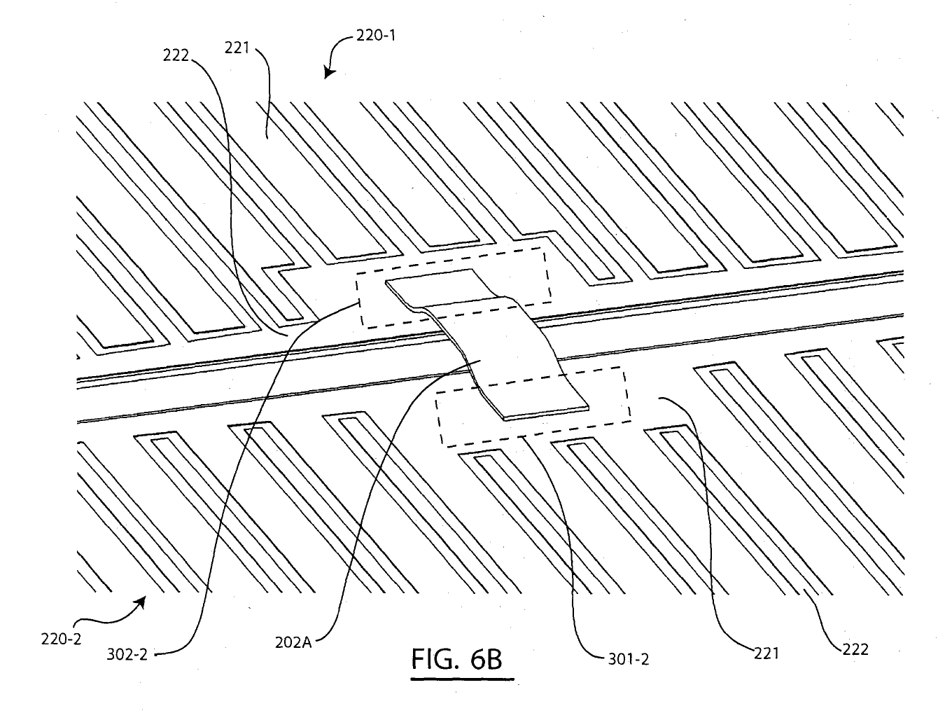

FIG. 6A shows a perspective view of two solar cells connected together using interconnect leads 202A in accordance with an embodiment of the present invention. In the example of FIG. 6A, interconnect leads 202A electrically connect three contact points on solar cell 220-1 to corresponding contact points on solar cell 220-2. Note the relatively small amount of space occupied by interconnect leads 202A on the conductive areas of the solar cells 220. This gives the solar cells 220 more room for efficiency-affecting structures such as interdigitated metal contacts. Also, interconnect leads 202A may be employed to connect larger solar cells by simply adding more interconnect leads 202A, if needed.

FIG. 6B shows a magnified view of the middle interconnect lead 202A of FIG. 6A. As shown in FIG. 6B, an interconnect lead 202A may be connected (e.g., by soldering) to a contact point (see dashed box 302-2) on conductive area 222 of solar cell 220-1 to a corresponding contact point (see dashed box 301-2) on conductive area 221 of solar cell 220-2.

Improved techniques for interconnecting solar cells have been disclosed. While specific embodiments of the present invention have been provided, it is to be understood that these embodiments are for illustration purposes and not limiting. Many additional embodiments will be apparent to persons of ordinary skill in the art reading this disclosure.

1. A solar cell array comprising:
a first solar cell having a backside comprising a first area of a first electrical polarity and a second area of a second electrical polarity; and
a plurality of contact points on the first area and the second area, the contact points on the first area being electrically coupled to corresponding contact points on an area on a backside of a second solar cell by separate pieces of interconnect leads.

2. The solar cell array of claim 1 wherein each of the first area and the second area has at least three contact points.

3. The solar cell array of claim 1 wherein each of the pieces of interconnect leads-comprises a strip of conductive material having a curve for strain relief.

4. The solar cell array of claim 3 wherein the strip of conductive material comprises copper coated with a material selected from a group comprising tin and solder.

5. The solar cell array of claim 1 wherein each of the pieces of interconnect leads comprises a strip of perforated conductive material.

6. The solar cell array of claim 1 wherein the pieces of interconnect leads comprise three interconnect leads.

7. The solar cell array of claim 1 wherein each of the pieces of interconnect leads is soldered to a contact point on the first area and to a corresponding contact point on the area on the backside of the second solar cell.

8. The solar cell array of claim 1 further comprising a bus bar electrically coupled to the second area.

9. The solar cell array of claim 1 further comprising a third solar cell having an area that is electrically coupled to the second area.

10. The solar cell array of claim 1 wherein the solar cell array is part of a solar cell module.

11. A solar cell array comprising a first backside-contact solar cell having a plurality of contact points that are electrically coupled by individual pieces of interconnect leads to corresponding contact points on a second backside-contact solar cell.

12. The solar cell array of claim 11 wherein at least one of the individual pieces of interconnect leads comprises a curved strip of conductive material.

13. The solar cell array of claim 12 wherein the curved strip of conductive material comprises copper having an outer coating.

14. The solar cell array of claim 13 wherein the outer coating comprises tin.

15. The solar cell array of claim 11 wherein at least one of the individual pieces of interconnect leads comprises a strip of perforated material.

16. The solar cell array of claim 11 wherein the individual pieces of interconnect leads comprise three interconnect leads.

17. A method of fabricating a solar cell array, the method comprising:
using a first interconnect lead to electrically couple a first contact point on a backside of a first solar cell to a second contact point on a backside of a second solar cell; and
using a second interconnect lead to electrically couple a third contact point on the backside of the first solar cell to a fourth contact point on the backside of the second solar cell, wherein the first contact point and the third contact point are on a conductive area on the backside of the first solar cell.

18. The method of claim 17 wherein the first interconnect lead comprises a curved strip of conductive material.

19. The method of claim 18 wherein the conductive material comprises copper coated with tin.

20. A solar cell array comprising:
a first backside-contact solar cell;
a second backside-contact solar cell adjacent to the first backside-contact solar cell in a solar cell array; and
a plurality of connection means for electrically coupling the first backside-contact solar cell to the second backside-contact solar cell.

21. The solar cell array of claim 20 further comprising a bus bar electrically coupled to the second backside-contact solar cell.

22. The solar cell array of claim 20 wherein each of the plurality of connection means comprises a strip of curved conductive material.
